(19) United States
(12) Patent Application Publication
(10) Pub. No.: US 2005/0040539 A1
(43) Pub. Date: Feb. 24, 2005

(54) Flip chip die bond pads, die bond pad placement and routing optimization

(76) Inventor: Eric Stephen Carlsgaard, Zionsville, IN (US)

Correspondence Address: Joseph S. Tripoli;Thomas Licensing Inc., Patent Department, P O Box 5312, Princeton, NJ, 08543-5312, US

(21) Appl. No.: 10/502,506

(22) PCT Filed: Jan. 31, 2003
(86) PCT No.: PCT/US03/02930

Related U.S. Application Data
(60) Provisional application No. 60/354,070, filed on Jan. 31, 2002.
(60) Provisional application No. 60/354,069, filed on Jan. 31, 2002.
(60) Provisional application No. 60/353,804, filed on Jan. 31, 2002.

(51) Int. Cl. H01L 23/48

(52) U.S. Cl. 257/778

(57) ABSTRACT

An integrated circuit die for a flip chip has circular die bond pads. Circular die bond pads allows for a higher density of bond pads when a mating printed circuit board has routing lines between its corresponding pads. In one form, there is provided a flip chip having a die and a plurality of die bond pads situated on the die. Each die bond pad of the die is circular.

This U.S. non-provisional patent application claims the benefit of and/or priority to U.S. provisional patent application Ser. No. 60/354,070 filed Jan. 31, 2002 entitled “Circular Die Bond Pads For Routing Optimization on a Mating Printed Circuit Board”; U.S. provisional patent application Ser. No. 60/354,069 filed Jan. 31, 2002 entitled “Die Bond Pad Placement Optimization For Minimal BGA PCB Layers”; and U.S. provisional patent application Ser. No. 60/353,804 filed Jan. 31, 2002 entitled “Die Size Minimization by Using Flip-Chip Bond Pad Placement and PCB Routing For Power and Ground.”

### BACKGROUND

1. Field of the Invention

The present invention concerns flip chips and, more particularly, to die bond pads, die bond pad placement and/or routing optimization for flip chips.

2. Background Information

Flip-chip technology requires a multi-layer printed circuit board (PCB) to support the routing of the bond pads on the integrated circuit die to the other integrated circuits (ICs) on the PCB or the external ball pads on a ball grid array (BGA). The greater the number of layers, the greater the cost of the PCB. The pitch (i.e. lines/pads plus spaces) on the POB has a limit to how fine it can be and still give reliable results. Moreover, the cost of the PCB increases as the pitch gets finer.

In standard flip-chip technology, the bond pads are square and placed evenly spaced in rows starting from the outer edge of the die and working inwards until the required number of connections is fulfilled. The pad pitch (i.e. pad size and spacing on the die) is set by the minimum that still gives high manufacturing yields when the die is soldered to the PCB (for example, 5 mil square pads and 3 mil spaces). The number of layers is then determined by the number of rows, plus typically power and/or ground layers. An example of the present pad placement scheme on the IC die is shown in the diagram of FIG. 1 depicting the present state of the art (i.e. prior art).

In FIG. 1, there is depicted a die 20 for an integrated circuit flip chip. The die 20 has a plurality of die bond or signal pads 22 distributed on one side of the die 20. While not evident in FIG. 1, each pad 22 is electrically coupled or connected to a component (not shown) such as a transistor, capacitor, resistor and/or the like of the integrated circuit or flip chip, to a power or ground bus or single terminal, or to other components of the IC or flip chip. The pads 22 are arranged in rows starting from a periphery of the die 20 and working inwardly. For the die 20 of FIG. 1, the pads 22 are arranged in a first outer row 24, a second or middle row 26, and an inner or last row 28. For a range of signal/bond pads 22 of greater than 232 but less than 337, this would require a 6-layer PCB, i.e. 3 layers for signals (3 outside rows of pads 22), 1 power, 1 ground, and 1 extra for signal or ground (since PCBs have an even number of layers). Thus, with current pad placement protocol, the PCB requires a large number of layers.

The size of the die is the primary driver of cost for an integrated circuit. When laying out the circuits on an IC, a significant portion of the die is used for large power busses to route the power and ground returns to all of the circuits. Ways to reduce the amount of the die spent on these power busses could help reduce the size, and therefore the cost, of the die.

In standard flip-chip technology, the power and ground pads are added inside of the signal rows to go to power and ground pads on the PCB. The routing on the flip-chip die is not significantly different from the routing done for edge pads in that the main power busses are run on the die. FIG. 2 shows a typical (prior art) die 36 with power 38 (dark) and ground 40 (white) busses crisscrossing the die 36 on a lower layer (or layers) of metal of the die 36 (illustrated by superimposing the power busses 38 and ground busses 40 over a layout of bond pads 42 in a manner like the pad layout of FIG. 1).

It is evident from the above that there is a need for optimization of bond pad placement.

### SUMMARY OF THE INVENTION

The subject invention is an integrated circuit die for a flip chip having circular die bond pads. Circular die bond pads allow for a higher density of bond pads when a mating printed circuit board has routing lines between its corresponding pads.

In one form, there is provided a flip chip having a die and a plurality of die bond pads situated on the die. Each die bond pad of the die is circular.

### BRIEF DESCRIPTION OF THE DRAWINGS

In the drawings:

FIG. 1 is a representation of an integrated circuit die of a flip chip showing prior art die bond pads and pad placement on the die;

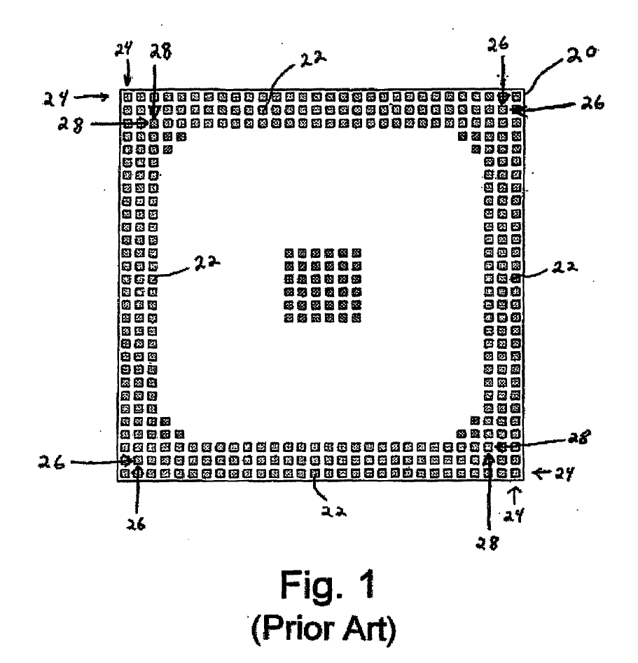

FIG. 2 is a representation of an integrated circuit die of a flip chip showing prior art placement of power and ground busses with respect to prior art bond pad placement;

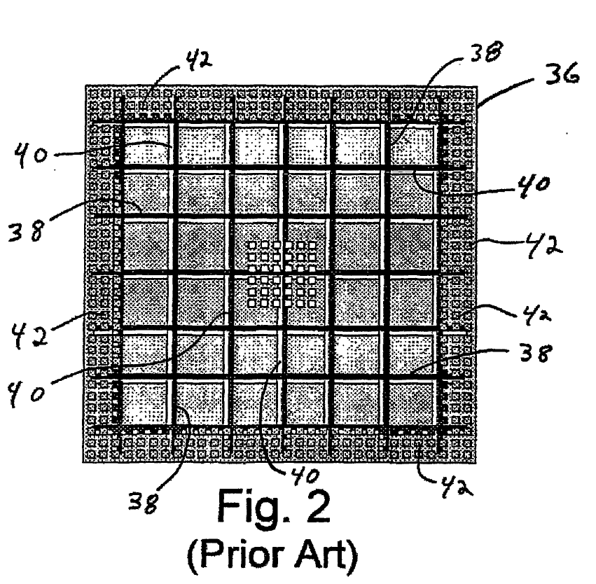

FIG. 3 is a representation of a portion of an integrated circuit die of a flip chip showing a portion of a bond pad arrangement particularly illustrating pitch requirements pertaining to routing lines with respect to the bond pad arrangement;

FIG. 4 is a representation of a portion of an integrated circuit die of a flip chip showing a portion of a bond pad arrangement particularly illustrating pitch requirements pertaining to routing lines with respect to the bond pad arrangement;

FIG. 5 is a representation of a portion of an integrated circuit die of a flip chip showing a portion of a bond pad arrangement particularly illustrating pitch requirements pertaining to routing lines with respect to the bond pad arrangement;

FIG. 6 is a representation of a die of a flip chip having bond pads distributed according to an exemplary arrangement, spacing, configuration or distribution pattern and depicting an exemplary manner of providing routing lines from respective bond pads, in accordance with the principles of the subject invention;

FIG. 7 is a representation of another die of a flip chip having bond pads distributed according to another exemplary arrangement, spacing, configuration or distribution pattern and depicting another exemplary manner of providing routing lines for respective bond pads, in accordance with the principles of the subject invention;

FIG. 8 is a representation of another die of a flip chip having bond pads distributed according to another exemplary arrangement, spacing, configuration or distribution pattern and depicting another exemplary manner of providing routing lines for respective bond pads, in accordance with the principles of the subject invention;

FIG. 9 is a representation of a portion of an integrated circuit die of a flip chip showing circular bond pads and an exemplary bond pad arrangement, spacing, configuration or distribution pattern thereof particularly illustrating pitch requirements pertaining to routing lines with respect to the bond pad arrangement in accordance with the principles of the subject invention;

FIG. 10 is a representation of a die of a flip chip having circular bond pads in accordance with an aspect of the subject invention, distributed according to an exemplary arrangement, spacing, configuration or distribution pattern and depicting an exemplary manner of providing routing lines from respective bond pads, in accordance with the principles of the subject invention;

FIG. 11 is a representation of a die of a flip chip depicting a manner of power and ground connections in accordance with the principles of the subject invention; and

FIG. 12 is a representation of a die of a flip chip depicting another manner of providing power and ground connections in accordance with the principles of the subject invention.

Corresponding reference characters indicate corresponding parts throughout the several views.

### DESCRIPTION OF THE PREFERRED EMBODIMENT(S)

In accordance with one aspect of the subject invention, a system, apparatus and/or method is described herein that provides for integrated circuit (IC) die bond placement that allows the number of layers on the mating printed circuit board (PCB) to be minimized. The IC die bond may be for a flip chip such as a flip chip ball grid array (BGA) application.

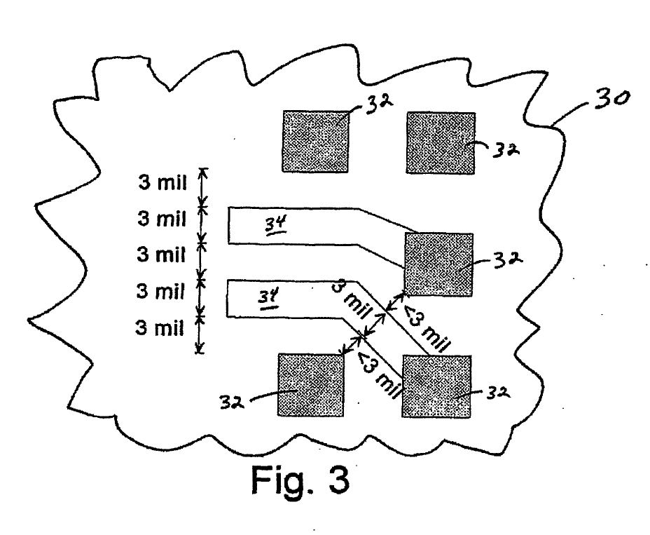

In one form thereof, this aspect takes into account the routing capabilities of the PCB and spaces every other row of bond pads such that two lines can be routed from the every other row of bond pads and between the outer row of bond pads relative thereto. This provides a staggered spacing for the bond pads. While there are many manners in which staggered spacing of the bond pads may be implemented in accordance with the principles of the subject invention, several manners and their consequential pitch are illustrated in FIGS. 3, 4 and 5.

When using routing between pads on the same layer of the mating PCB, the limit on the pitch may not allow the lines to route between the pads when in the standard aligned arrangement and thus the staggered spacing. One manner of staggered spacing is illustrated in FIG. 3. In FIG. 3, there is depicted a portion of an integrated circuit (flip chip) die 30 on which are situated a plurality of pads 32. Also shown are two routing lines 34. The pads 32 form a first (right) row and a second (left) row that together form a row pair. The first row contains two pads 32 for three pads 32 of the second row. The exemplary staggered spacing of FIG. 3 in accordance with the principles of the subject invention, provides a routing line 34 that may be within less than 3 mils from a pad 32. Such staggered spacing, however, provides for two routing lines 34 between the first row. This allows for less layers on a mating PCB.

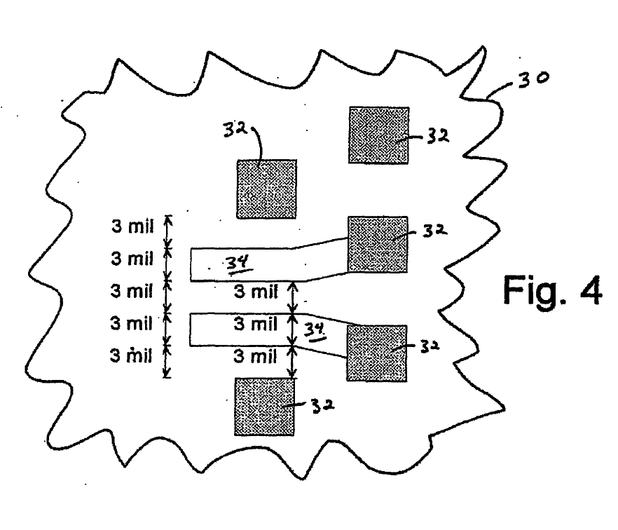

In order to provide at least a 3 mil spacing, the arrangement of the pads 32 may be forced to be offset from row to row. This is illustrated in FIG. 4. In FIG. 4, the first (right) row of pads 32 is offset from the second (left) row of pads. In this manner the routing lines 34 maintain a 3 mil spacing from each other and the pads 32.

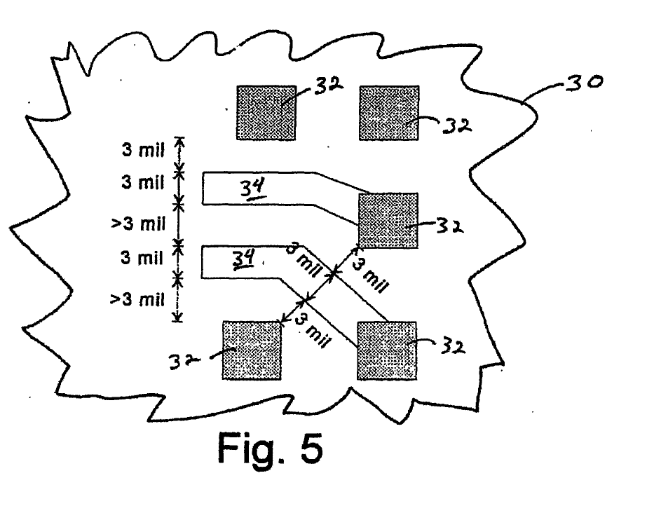

Another manner of abiding by the pitch rules is to force the aligned rows to be farther apart. This is illustrated in FIG. 5. In FIG. 5, the aligned row of pads 32 is at least 3 mil in spacing apart and, in some instances, is greater than 3 mils apart.

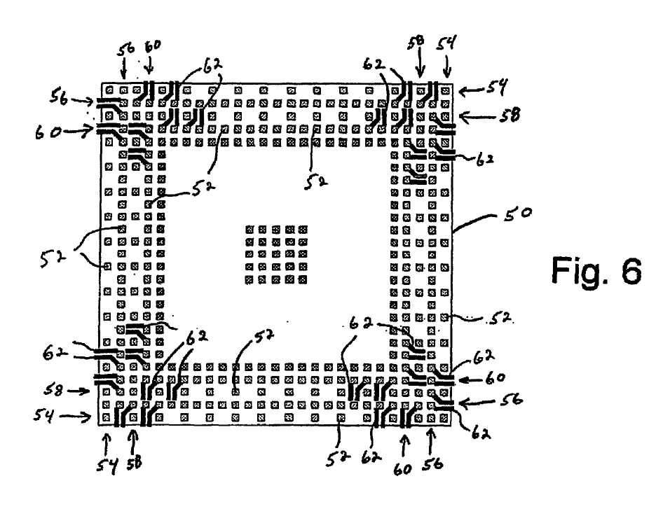

Referring now to FIG. 6, there is depicted an example of the staggered spacing bond pads with respect to an entire die. In FIG. 6 there is depicted a die 50 such as for a flip chip on which is disposed a plurality of bond pads 52. The bond pads 52 are situated on the die bond 50 such that there is a plurality of adjacent rows of bond pads starting from an outer periphery of the die bond 50. As seen in FIG. 6, a first plurality of bond pads 52 are arranged in a first outer row 54. The outer row 54 of bond pads 52 is arranged such that the pitch (pad 52 plus spacing) of the bond pads 52 constituting the outer row 54 allows a second or first inner row 56 of a second plurality of bond pads 52 to be arranged such that the pitch of the bond pads 52 constituting the second row 56 to be one-half of the pitch of the outer row 54. The second row 56 pitch is limited by the technology constraints of minimum pitch for high yield (as used today for all rows). This allows two routing lines 62, each one connected to an adjacent bond pad 52 of the second row 56, to be routed between adjacent bond pads 52 of the first row 54.

The first and second rows 54 and 56 may be considered an outer row and an inner row pair. Thus, the inner row 56 of bond pads 52 can be aligned with the outer row 54 or offset to center them on the spacing to give more direct routing. In this manner, routing lines 62 of the two rows of bond pads 52 (i.e. the inner 56 and outer 54 rows) are routed on every layer of a mating PCB (not shown). This is accomplished for all of the bond (signal) pads 52. Thus, the third row 58 of a third plurality of bond pads 52 is arranged in the same manner as the first row 54. The third row 58 thus constitutes an outer row of bond pads 52. In like manner, the fourth row 60 of a fourth plurality of bond pads 52 is arranged in the same manner as the second row 56. The fourth row 60 thus constitutes an inner row of bond pads 52. The third 58 and fourth 60 rows of bond pads constitutes a second pair of bond pads 52. Again, in this manner, routing lines 62 of the two rows of bond pads 52 (i.e. the inner 60 and outer 58 rows) are routed on every layer of the mating PCB. More or less row pairs may be provided on the die 50 as appropriate. The configuration depicted in FIG. 6 provides placement of bond pads of a 372 connection die (280 signal).

The power and ground use their own rows or groups of pads and route to respective layers on the mating PCB, such as the group of pads in the center of the die and the innermost row of pads from the periphery of the die. It should be appreciated that FIG. 6 does not depict every routing line. It should also be appreciated that the routing lines 62 are of the PCB. The routing lines 62 shown in FIG. 6 are thus exemplary of the many routing lines of the PCB and are overlaid on the die bond 50 to show how the double-pitch inner row is routed on the same layer of the outer row. The exemplary die 50 requires only a four(4)-layer PCB: i.e. two (2) layers for the four rows of signal pads, plus one (1) power and one (1) ground.

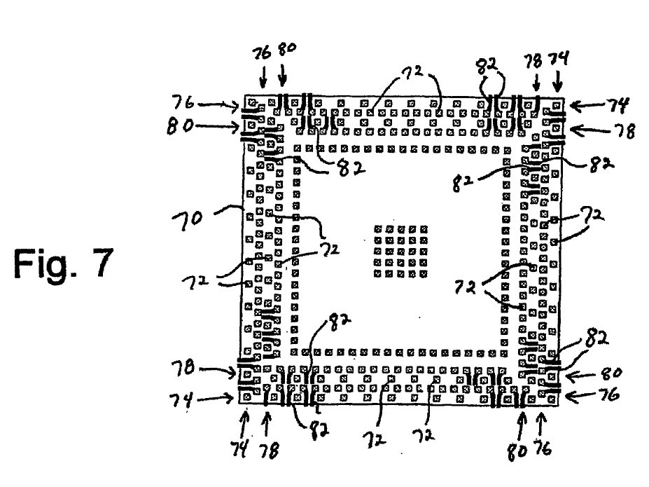

Referring to FIG. 7, there is shown a die 70 such as for a flip chip on which is disposed a plurality of bond pads 72. The bond pad arrangement on the die 70 provides a slightly different routing scheme for the routing lines 82. Particularly, the bond pads 72 are situated on the die bond 70 such that there is a plurality of adjacent rows of bond pads starting from an outer periphery of the die bond 70. As seen in FIG. 7, a first plurality of bond pads 72 are arranged in a first outer row 74. The outer row 74 of bond pads 52 is arranged such that the pitch (pad 72 plus spacing) of the bond pads 72 constituting the outer row 74 allows a second or first inner row 76 of a second plurality of bond pads 72 to be arranged such that the pitch of the bond pads 72 constituting the second row 76 to be one-half of the pitch of the outer row 74. The second row 76 pitch is limited by the technology constraints of minimum pitch for high yield (as used today for all rows). In this example, however, the second row 76 is offset from the first row 74. This gives a more direct routing of the routing lines 82 of the PCB. This allows two routing lines 82, each one connected to an adjacent bond pad 72 of the second row 76, to be routed between adjacent bond pads 72 of the first row 74. This arrangement, however, results in a slightly lower number of signal pins (bond pads) than the exemplary die 50 of FIG. 6, but is typically sufficient in various cases. Particularly, the exemplary die 70 provides a 372 connection (278 signal) arrangement.

The first and second rows 74 and 76 may be considered an outer row and an inner row pair. Thus, the inner row 76 of bond pads 72 is offset on the spacing relative to the outer row 74 to give a more direct routing of the routing lines 82. In this manner, routing lines 82 of the two rows of bond pads 72 (i.e. the inner 76 and outer 74 rows) are routed on every layer of a mating PCB (not shown). This is accomplished for all of the bond (signal) pads 72. Thus, the third row 78 of a third plurality of bond pads 72 is arranged in the same manner as the first row 74. The third row 78 thus constitutes an outer row of bond pads 72. In like manner, the fourth row 80 of a fourth plurality of bond pads 72 is arranged in the same manner as the second row 76. The fourth row 80 thus constitutes an inner row of bond pads 72.

The third 78 and fourth 80 rows of bond pads constitutes a second pair of bond pads 72. Again, in this manner, routing lines 82 of the two rows of bond pads 72 (i.e. the inner 80 and outer 78 rows) are routed on every layer of the mating PCB. More or less row pairs may be provided on the die 50 as appropriate.

The power and ground use their own rows or groups of pads and route to respective layers on the mating PCB. It should be appreciated that FIG. 7 does not depict every routing line. It should also be appreciated that the routing lines 82 are of the PCB. The routing lines 82 shown in FIG. 7 are thus exemplary of the many routing lines of the PCB and are overlaid on the die bond 70 to show how the double-pitch inner row is routed on the same layer of the outer row. The exemplary die 70 requires only a four(4)-layer PCB: i.e. two (2) layers for the four rows of signal pads, plus one (1) power and one (1) ground.

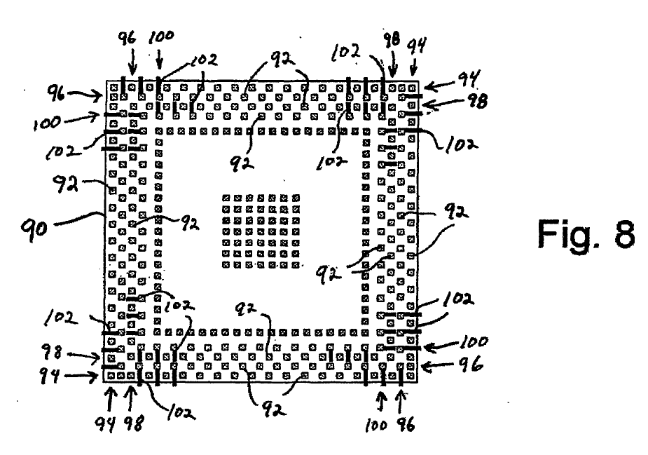

Referring to FIG. 8, there is shown a die 90 such as for a flip chip on which is disposed a plurality of bond pads 92. The bond pad arrangement on the die 90 provides another alternative implementation or slightly different routing scheme for the routing lines 102. Particularly, the bond pads 92 are situated on the die bond 90 such that there is a plurality of adjacent rows of bond pads starting from an outer periphery of the die bond 90. As seen in FIG. 8, a first plurality of bond pads 92 are arranged in a first outer row 94. The outer row 94 of bond pads 92 is arranged such that the pitch (pad 92 plus spacing) of the bond pads 92 constituting the outer row 94 allows a second or first inner row 96 of a second plurality of bond pads 92 to be arranged such that the pitch of the bond pads 92 constituting the second row 96 to be the same pitch as the outer row 94. The inner row 96 uses the same spacing as the outer tow 94. In this example, however, the second row 96 is offset from the first row 94, particularly such that each bond pad 92 of the second row 96 is in the middle of the spacing between adjacent bond pads 92 of the first row 94. This gives a more direct routing of the routing lines 92 of the PCB. This, however, allows only a single routing line 102 to be routed from a bond pad 92 of the second row 96 between adjacent bond pads 92 of the first row 94. This arrangement, however, results in a slightly lower number of signal pins (bond pads) than the exemplary dies 50 and 70 of FIGS. 6 and 7 respectively, but is typically sufficient in various cases. Particularly, the exemplary die 90 provides a 372 connection (252 signal) arrangement.

The first and second rows 94 and 96 may be considered an outer row and an inner row pair. Thus, the inner row 96 of bond pads 92 is offset on the spacing relative to the outer row 94 to give a more direct routing of the routing lines 102. In this manner, routing lines 102 of the two rows of bond pads 92 (i.e. the inner 96 and outer 94 rows) are routed on every layer of a mating PCB (not shown). This is accomplished for all of the bond (signal) pads 92. Thus, the third row 98 of a third plurality of bond pads 92 is arranged in the same manner as the first row 94. The third row 98 thus constitutes an outer row of bond pads 92. In like manner, the fourth row 100 of a fourth plurality of bond pads 92 is arranged in the same manner as the second row 96. The fourth row 100 thus constitutes an inner row of bond pads 92. The third 98 and fourth 100 rows of bond pads constitutes a second pair of bond pads 92. Again, in this manner, routing lines 102 of the two rows of bond pads 92 (i.e. the inner 100 and outer 98 rows) are routed on every layer of the mating PCB.

The power and ground use their own rows or groups of pads and route to respective layers on the mating PCB. It should be appreciated that FIG. 8 does not depict every routing line. It should also be appreciated that the routing lines 102 are of the PCB. The routing lines 102 shown in FIG. 8 are thus exemplary of the many routing lines of the PCB and are overlaid on the die bond 90 to show how the routing lines are routed. The exemplary die 90 requires only a four(4)-layer PCB: i.e. two (2) layers for the four rows of signal pads, plus one (1) power and one (1) ground.

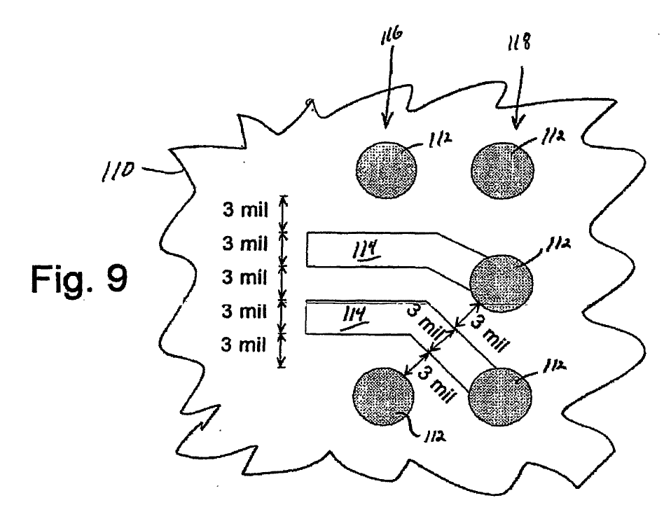

In accordance with another aspect of the subject invention, a die, particularly for a flip chip, is provided circular bond pads. Circular bond pads achieve an optimum density of pads on the die that comes with mostly aligned pad rows while still satisfying the line pitch rules of a mating PCB (not shown). The use of circular bond pads on the integrated circuit die surface allows for a higher density of these pads when the mating PCB has routing lines between its corresponding pads. Referring now to FIG. 9, there is illustrated a portion of a die 110. The die 110 has a plurality of circular bond pads 112 situated thereon. It should be appreciated that FIG. 9 only depicts a portion of a die and thus the entire die preferably, but not necessarily, has only circular bond pads 112. Two routing lines 114 are depicted as overlaid on the die 110 to illustrate the satisfaction of the pitch requirements with staggered rows (row pairs) of circular bond pads 112.

Calculations show that circular bond pads provide an increase of nearly 30% in the spacing between the pads can be gained by changing from square to circular bond pads. For example, diagonal square pads (5 mil sides) of two aligned rows at 5 mil spacing (10 mil pitch) are spaced at:
((Pad Pitch)/2)*(2^{1/2})=(10/2)*1.414=7.07 mils.

However, diagonal circular pads 112 of the same size (5 mil diameter) of two aligned rows at 5 mil spacing (10 mil pitch) are spaced at:
(Pad Pitch)*(2^{1/2})−(Radius of pad A+Radius of Pad B)=(10)*1.414−(5)=9.14 mils.

In FIG. 9, two PCB routing lines 114 are depicted. In this exemplary bond pad 112 arrangement, there are 3 mil lines and spaces on the PCB (not shown) and 5 mil diameter circular bond pads 112 with 5 mil spacing on the die 110. FIG. 9 clearly shows that the routing lines 114 route to an inner row 116 relative to an outer row 118 of a plurality of bond pads 112, without violating the line pitch rules of the PCB.

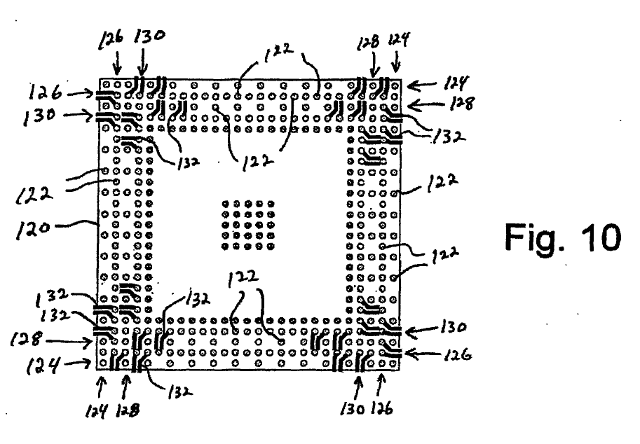

Referring now to FIG. 10, an exemplary die 120 is depicted that utilizes the bond pad arrangement and style (i.e. circular bond pads) illustrated in FIG. 9. Particularly, there is provided four rows 124, 126, 128 and 130 of bond pads 122 arranged from an outer periphery of the die 120 inward. As with the previous exemplary dies and bond pad patterns, adjacent rows of bond pads 122 form row pairs of inner and outer rows. In FIG. 10, the outer rows 124 and 128 of bond pads 122 are spaced at double the pitch with respect to the respective inner rows 126 and 130. In this manner, two routing lines 132 may be routed from adjacent bond pads 122 of the inner rows 126 and 130 between the respective outer rows 124 and 128.

The power and ground use their own rows or groups of pads and route to respective layers on the mating PCB. It should be appreciated that FIG. 10 does not depict every routing line. It should also be appreciated that the routing lines 132 are of the PCB. The routing lines 132 shown in FIG. 10 are thus exemplary of the many routing lines of the PCB and are overlaid on the die bond 120 to show how the routing lines are routed. The exemplary die 120 requires only a four(4)-layer PCB: i.e. two (2) layers for the four rows of signal pads, plus one (1) power and one (1) ground. In this example of circular bond pad 122 arrangement on the die 120, a maximum number of signal (bond) pads for a set number of layers of PCB per die area is achieved. In FIG. 10, 56+96+48+80=280 signal pads 122 are provided on the outer four rows 124, 126, 128 and 130, that can be routed on the two (2) signal layers of the mating PCB (not shown).

In accordance with another aspect of the subject invention, a system, apparatus and/or method is described that provides a combination of strategic placement of flip chip bond pads on an integrated circuit (IC) die surface and power and ground planes on the associated printed circuit board (PCB) minimizing the die size of the IC by eliminating much of the power and ground routing on the die itself. This also has the potential to save on the number of metal layers needed on the die, further reducing the cost (and number of process steps in the fabrication of the IC).

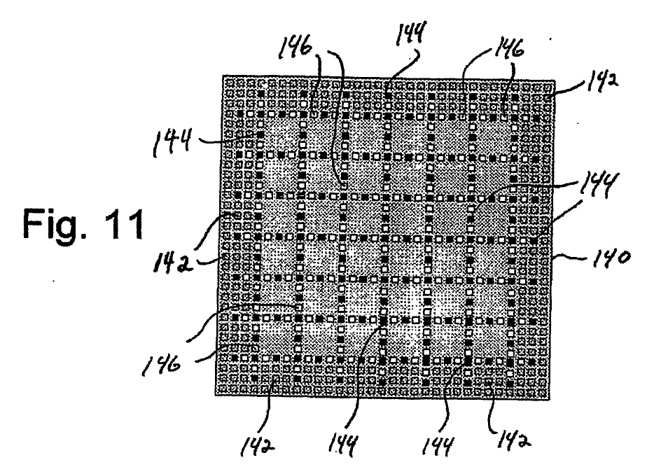

Referring now to FIG. 11, there is depicted an exemplary manner of providing power and ground planes on an IC die 140. The die 140 has a plurality of square or circular bond pads 142 arranged in any manner as described above, but shown in four adjacent rows from an outside periphery of the die 140 inwardly. The die 140 further has a plurality of power pads (black) 144 and a plurality ground pads (white) 146 arranged thereon. Particularly, the power pads 144 and the ground pads 146 are arranged or distributed in rows on the die surface. These power and ground pads will supply their respective circuits (not shown) so that only very localized power and ground routing is necessary. In FIG. 11, the power pads 144 are arranged in spaced, criss-cross rows. The ground pads 146 are arranged in the spaced, cross-cross power pads rows between adjacent power pads 144. In this embodiment, there are seven (7) criss-crossed rows and columns of power and ground pads. It should be appreciated that the pads may be circular rather than square, as with all of the Figures.

These power and ground pads are then soldered to the PCB (not shown) in the flip chip process. The PCB joins the power and ground together through a very low impedance power or ground plane. The die 140 of FIG. 11 uses a six (6)-layer PCB: three (3) layers for the three (3) rows of signal (bond) pads 142 (total of 280 signals), plus one (1) power, one (1) ground and one extra plane (since the PCB requires an even number of layers). This sixth plane could be used for a second power supply that may be needed for the IC. For example, one power supply may be for the I/O circuits (e.g. at 3.3 volts) and one power supply for the core circuits (e.g. at 1.8 volts).

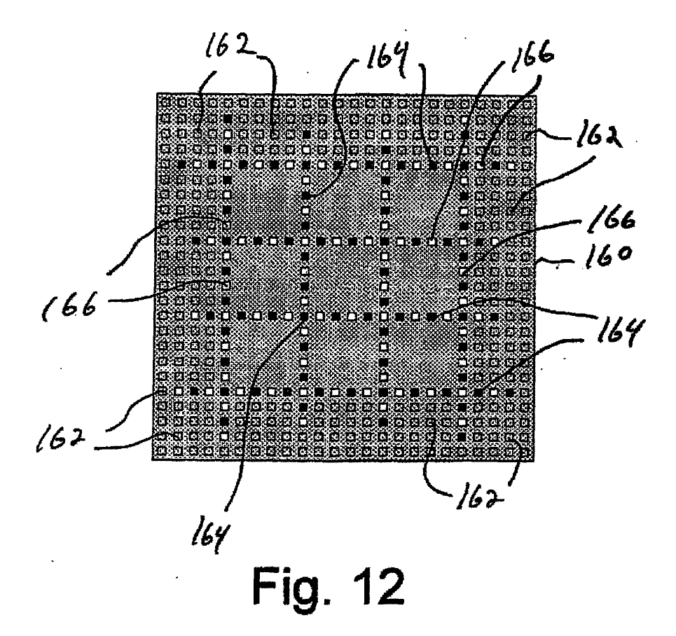

Referring to FIG. 12, there is depicted another example of an exemplary manner of providing power and ground planes on an IC die 160. The die 160 has a plurality of square or circular bond pads 162 arranged in any manner as described above, but shown in four adjacent rows from an outside periphery of the die 160 inwardly. The die 160 further has a plurality of power pads (black) 164 and a plurality ground pads (white) 166 arranged thereon. Particularly, the power pads 164 and the ground pads 166 are arranged or distributed in rows on the die surface. These power and ground pads will supply their respective circuits (not shown) so that only very localized power and ground routing is necessary. In FIG. 12, the power pads 164 are arranged in spaced, criss-cross rows. The ground pads 166 are arranged in the spaced, cross-cross power pads rows between adjacent power pads 164. In this embodiment, there are four (4) criss-crossed rows and columns of power and ground pads.

These power and ground pads are then soldered to the PCB (not shown) in the flip chip process. The PCB joins the power and ground together through a very low impedance power or ground plane. The die 160 of FIG. 12 uses a six (6)-layer PCB: four (4) layers for the four (4) rows of signal (bond) pads 162 (total of 280 signals), plus one (1) power and one (1) ground. While this die 160 has a mating or corresponding 6-layer PCB (not shown), it is more suitable for pad-limited designs where the core circuitry is not the limiting factor on the die size.

While this invention has been described as having a preferred design, the present invention can be further modified within the spirit and scope of this disclosure. This application is therefore intended to cover any variations, uses, of adaptations of the invention using its general principles. Further, this application is intended to cover such departures from the present disclosure as come within known or customary practice in the art to which this invention pertains and which fall within the limits of the appended claims.

1. An integrated circuit die for a flip chip comprising:
a die; and
a plurality of die bond pads situated on said die wherein said die bond pads are situated in rows with every other row having a bond pad spacing different than that of a bond pad spacing of an adjacent row.

2. The integrated circuit die of claim 1, wherein said plurality of die bond pads is positioned proximate an outside surface of said die.

3. The integrated circuit die of claim 1, wherein the bond pad spacing of every other row is twice the bond pad spacing of an adjacent row.

4. The integrated circuit die of claim 1, wherein said die bond pads situated in rows define row pairs, a first row of a row pair having a first bond pad spacing defining a first pitch, and a second row of the row pair having a second bond pad spacing defining a second pitch that is different than that of said first pitch.

5. The integrated circuit die of claim 4, wherein said first row of the row pair is situated proximate an outside edge of said die.

6. The integrated circuit die of claim 1, wherein each die bond pad is circular.

7. The integrated circuit die of claim 6, wherein each circular bond pad has a diameter of approximately 5 mils.

8. An integrated circuit die for a flip chip comprising:
die means; and
a plurality of die bond pads situated on said die means wherein said die bond pads are situated in rows with every other row having a bond pad spacing different than that of a bond pad spacing of an adjacent row.

9. The integrated circuit die of claim 8, wherein said rows of said plurality of die bond pads are positioned proximate an outside surface of said die means.

10. The integrated circuit die of claim 9, wherein the bond pad spacing of every other row is twice the bond pad spacing of an adjacent row.

11. The integrated circuit die of claim 9, wherein said die bond pads are situated in rows defining row pairs, a first row of a row pair having a first bond pad spacing defining a first pitch, and a second row of the row pair having a second bond pad spacing defining a second pitch that is different than that of said first pitch.

12. The integrated circuit die of claim 11, wherein said first row of the row pair is situated proximate an outside edge of said die means.

13. The integrated circuit die of claim 8, wherein each die bond pad is circular.

14. The integrated circuit die of claim 13, wherein each circular bond pad has a diameter of approximately 5 mils.

15. A method of fabricating an integrated circuit die for a flip chip comprising the steps of:
providing an integrated circuit die; and
providing a plurality of die bond pads situated on said integrated circuit die wherein said plurality of die bond pads are situated in rows with every other row having a bond pad spacing different than that of a bond pad spacing of an adjacent row.

16. The integrated circuit die of claim 15, wherein said step of providing a plurality of die bond pads comprises positioning the rows of die bond pads proximate an outside surface of said die.

17. The integrated circuit die of claim 16, wherein the step of providing rows of bond pads beginning proximate an outside surface of said integrated circuit die includes the step of providing rows of bond pads with every other row having a bond pad spacing twice that of a bond pad spacing of an adjacent row.

18. The method of claim 16, wherein the step of providing rows of bond pads with every other row having a bond pad spacing different than that of a bond pad spacing of an adjacent row includes the step of situating the bond pads in rows defining row pairs, a first row of a row pair having a first bond pad spacing defining a first pitch, and a second row of the row pair having a second bond pad spacing defining a second pitch that is different than that of said first pitch.

19. The method of claim 18, wherein said first row of the row pair is situated proximate an outside edge of said die.

20. The method of claim 15, wherein each die bond pad is circular.

21. The method of claim 20, wherein each circular die bond pad has a diameter of approximately 5 mils.
